(19) United States
(12) Patent Application Publication
(10) Pub. No.: US 2016/0005788 A1
(43) Pub. Date: Jan. 7, 2016

(54) SOLID-STATE IMAGING APPARATUS AND IMAGING SYSTEM

(71) Applicant: CANON KABUSHIKI KAISHA, Tokyo (JP)

(72) Inventors: Masanori Ogura, Tokyo (JP); Takahiro Shirai, Isehara-shi (JP)

(21) Appl. No.: 14/788,858

(22) Filed: Jul. 1, 2015

(30) Foreign Application Priority Data
Jul. 7, 2014 (JP) 2014-139605

(51) Int. Cl. H01L 27/148; H01L 27/146; H04N 3/14

(52) U.S. Cl. CPC H01L 27/14812; H04N 3/155; H01L 27/14638; H01L 27/14616; H01L 27/14636; H01L 27/14621

(57) ABSTRACT

Provided is a solid-state imaging apparatus including plural pixels each including a first pixel connecting transistor and a second pixel connecting transistor each connected at one end to a floating diffusion node, a first pixel connecting line connected to the other end of the first pixel connecting transistor, and a second pixel connecting line connected to the other end of the second pixel connecting transistor. The first pixel connecting line provided in a first pixel of the plural pixels is connected to the second pixel connecting line provided in a second pixel of the plural pixels, and the second pixel connecting line provided in the first pixel is connected to the first pixel connecting line provided in a third pixel of the plural pixels.

### BACKGROUND OF THE INVENTION

1. Field of the Invention

The present invention relates to a solid-state imaging apparatus and an imaging system.

2. Description of the Related Art

A solid-state imaging apparatus having a function of averaging pixel signals outputted from plural photoelectric converters is disclosed in Japanese Patent Application Laid-Open No. 2009-16972 and Japanese Patent Application Laid-Open No. 2013-197951.

The solid-state imaging apparatus disclosed in Japanese Patent Application Laid-Open No. 2009-16972 includes a pixel connecting line for connecting together floating diffusions of plural pixels in a pixel block. Connection or disconnection between the floating diffusions and the pixel connecting line is switch-selectable. Thus, the solid-state imaging apparatus disclosed in Japanese Patent Application Laid-Open No. 2009-16972 can operate in two modes: specifically, a mode of reading an averaged pixel signals (a mixing/thinning-out scan reading mode), and a mode of individually reading each pixel signal (a non-mixing/all-pixel reading mode).

The solid-state imaging apparatus disclosed in Japanese Patent Application Laid-Open No. 2013-197951 includes a connection transistor configured to provide connection or disconnection between the floating diffusions. Turning on the connection transistor allows the floating diffusions to be connected together, thereby averaging the pixel signals.

When the solid-state imaging apparatus disclosed in Japanese Patent Application Laid-Open No. 2009-16972 is in the non-mixing/all-pixel reading mode, the pixel connecting line is not connected to each individual floating diffusion. Meanwhile, when the apparatus is in the mixing/thinning-out scan reading mode, the pixel connecting line is connected to each floating diffusion. The pixel connecting line has a parasitic capacitance, and the pixel connecting line is connected to each floating diffusion thereby to combine the parasitic capacitance with a capacitance of the floating diffusion and hence increase a capacitance value. A configuration disclosed in Japanese Patent Application Laid-Open No. 2009-16972 needs a corresponding number of pixel connecting lines to the number A of pixels in the pixel block, and thus, the larger the number A of pixels, the larger the parasitic capacitance caused by the pixel connecting lines.

Discussion will now be given for example for a case where two floating diffusions, which are fewer than the number A of pixels, are connected together. Here, the capacitance of the pixel connecting line per pixel is represented by C_{C}; the capacitance of the floating diffusion, C_{FD}; and a signal electric charge outputted from each photoelectric converter, Q. In this case, a value of a sum total of the signal electric charges is 2Q; the capacitance value of the two floating diffusions, 2C_{FD}; and the capacitance of the pixel connecting lines, A×C_{C}. Thus, a voltage of the floating diffusions is 2Q/(2C_{FD}+A×C_{C}), which in turn reduces sensitivity, as compared to the voltage, 2Q/2C_{FD}, in the absence of the parasitic capacitance. Therefore, the solid-state imaging apparatus disclosed in Japanese Patent Application Laid-Open No. 2009-16972 may pose a problem of reduction in the sensitivity, when operated in the mode of averaging. This problem is noticeable, particularly in a case where the number A of pixels in the pixel block is large and the number of pixel signals averaged is small.

Also, the solid-state imaging apparatus disclosed in Japanese Patent Application Laid-Open No. 2013-197951 uses the single connection transistor to control connection or disconnection between the floating diffusions. In this configuration, even when the averaging of the pixel signals is not performed, the parasitic capacitance of a line connecting the floating diffusions and the connection transistor is added to the capacitance of the floating diffusions. Thus, the solid-state imaging apparatus disclosed in Japanese Patent Application Laid-Open No. 2013-197951 may pose a problem of reduction in sensitivity even in a mode in which the averaging is not performed.

### SUMMARY OF THE INVENTION

There is provided a solid-state imaging apparatus according to one embodiment of the present invention including: plural pixels each including a photoelectric converter configured to generate an electric charge by photoelectric conversion, a transfer transistor configured to transfer the electric charge, a floating diffusion node configured to hold the electric charge by transferred by the transfer transistor, a source follower transistor configured to output a signal based on an electric potential of the floating diffusion node, a first pixel connecting transistor and a second pixel connecting transistor each having a drain node and a source node, one of the drain node and the source node being connected to the floating diffusion node, a first pixel connecting line connected to the other of the drain node and the source node of the first pixel connecting transistor, and a second pixel connecting line connected to the other of the drain node and the source node of the second pixel connecting transistor. The first pixel connecting line included in a first pixel of the plural pixels is connected to the second pixel connecting line included in a second pixel of the plural pixels, and the second pixel connecting line included in the first pixel is connected to the first pixel connecting line included in a third pixel of the plural pixels.

Further features of the present invention will become apparent from the following description of exemplary embodiments with reference to the attached drawings.

### BRIEF DESCRIPTION OF THE DRAWINGS

FIG. 1A is a circuit diagram illustrating a configuration of a solid-state imaging apparatus according to a first embodiment of the present invention.

FIG. 1B is a circuit diagram illustrating a configuration of a pixel according to the first embodiment of the present invention.

FIG. 2 is a drive timing chart of the solid-state imaging apparatus according to the first embodiment of the present invention.

FIG. 3 is a drive timing chart of the solid-state imaging apparatus according to the first embodiment of the present invention.

FIG. 4 is a drive timing chart of the solid-state imaging apparatus according to the first embodiment of the present invention.

FIG. 5 is a plan view illustrating the configuration of the solid-state imaging apparatus according to the first embodiment of the present invention.

FIG. 6 is a plan view illustrating the configuration of the solid-state imaging apparatus according to the first embodiment of the present invention.

FIG. 7 is a drive timing chart of a solid-state imaging apparatus according to a second embodiment of the present invention.

FIG. 8 is a drive timing chart of a solid-state imaging apparatus according to a third embodiment of the present invention.

FIG. 9A is a circuit diagram illustrating a configuration of a solid-state imaging apparatus according to a fourth embodiment of the present invention.

FIG. 9B is a circuit diagram illustrating a configuration of a pixel according to the fourth embodiment of the present invention.

FIG. 10 is a drive timing chart of the solid-state imaging apparatus according to the fourth embodiment of the present invention.

FIG. 11 is a plan view illustrating the configuration of the solid-state imaging apparatus according to the fourth embodiment of the present invention.

FIG. 12 is a block diagram illustrating a configuration of an imaging system according to a fifth embodiment of the present invention.

### DESCRIPTION OF THE EMBODIMENTS

Preferred embodiments of the present invention will now be described in detail in accordance with the accompanying drawings. In the drawings of the embodiments, elements having the same functions are indicated by the same reference numerals, and repeated description of the elements will sometimes be omitted.

### First Embodiment

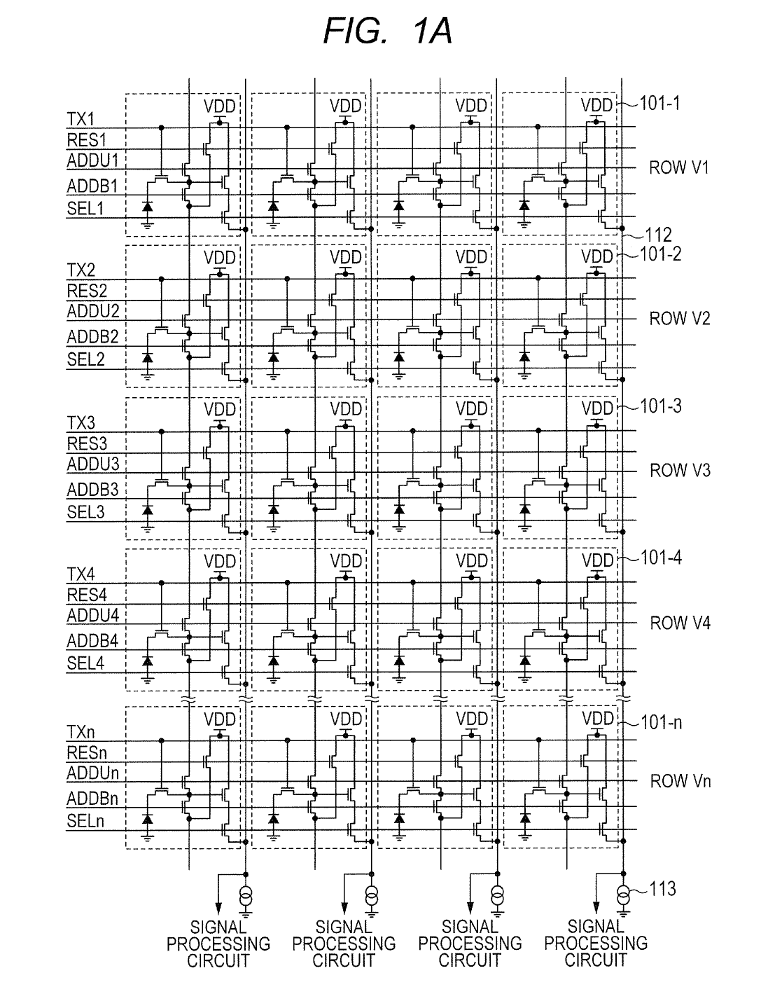

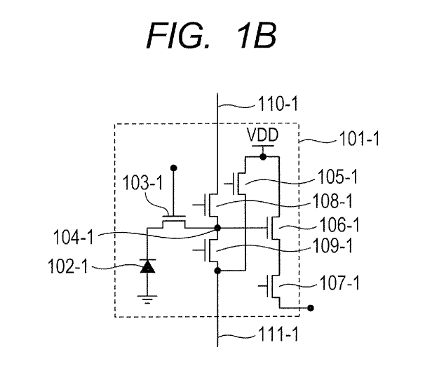

FIGS. 1A and 1B are circuit diagrams illustrating a configuration of a solid-state imaging apparatus according to a first embodiment of the present invention. The solid-state imaging apparatus illustrated in FIG. 1A includes plural pixels 101-1, 101-2, . . . , 101-n arrayed in matrix, a vertical signal line 112 connected in common for each pixel column, and a current source 113. (Note that indices indicate row numbers, and the same goes for the following description.) The solid-state imaging apparatus of the embodiment is an apparatus using a CMOS (Complementary Metal-Oxide-Semiconductor), for example, and is formed on a semiconductor substrate such as a silicon substrate. In FIG. 1A, a matrix with 5 rows and 4 columns is illustrated but is illustrative only, and the numbers of rows and columns may be set to any number. For example, the number of pixels may be set to form a matrix with several thousands of rows and several thousands of columns. In the embodiment, description of a circuit configuration will be given focusing on a certain column; description thereof will be omitted, assuming that the other columns also have the same circuit configuration.

Description will be given below with regard to the circuit configuration of the pixel 101-1 in the first row in FIG. 1A. Description will be omitted, assuming that the pixels 101-2, . . . , 101-n in the other rows also may include the same circuit. FIG. 1B is a diagram illustrating the circuit configuration of the pixel 101-1. The pixel 101-1 includes a photoelectric converter 102-1, a transfer transistor 103-1, a reset transistor 105-1, a source follower transistor (hereinafter called an SF transistor) 106-1, and a row select transistor 107-1. Each transistor in the pixel 101-1 is constructed of a MOSFET (MOS Field Effect Transistor) or the like. In the following description, each transistor is assumed to be an N type MOSFET.

The photoelectric converter 102-1 is an element configured to generate an electric charge according to the amount of incident light, and is constructed of a photodiode or the like. The photoelectric converter 102-1 is connected via the transfer transistor 103-1 to a floating diffusion node (hereinafter called an FD node) 104-1 as a gate node of the SF transistor 106-1.

The pixel 101-1 further includes pixel connecting transistors 108-1, 109-1 each connected at one end, which is either a source node or a drain node, to the FD node 104-1. The other ends of the pixel connecting transistors 108-1, 109-1 are connected to pixel connecting lines 110-1, 111-1, respectively. Hereinafter, a mere expression such as “connected to the pixel connecting transistor(s)” indicates that a terminal connected is any one of the source node and the drain node.

The pixel connecting lines 110-1, 111-1 are connected to the pixel connecting lines of an adjacent pixel in a column direction. For example, the pixel connecting transistor 109-1 is connected via the pixel connecting line 111-1 to a pixel connecting line 110-2 of the adjacent pixel 101-2. The pixel connecting line 110-2 is connected via a pixel connecting transistor 108-2 to an FD node 104-2. Thus, the FD nodes of the adjacent pixels in the column direction are connected together via the two pixel connecting transistors. Although the pixel connecting transistor 109-1 is illustrated as being connected to the pixel connecting transistor 108-2 via separate lines indicated by two different reference numerals, respectively, namely, the pixel connecting lines 111-1, 110-2, the lines may be actually constructed of a single line provided in common.

A power supply voltage VDD is inputted to a drain of the SF transistor 106-1, and a source of the SF transistor 106-1 is connected to a drain of the row select transistor 107-1. A source of the row select transistor 107-1 is connected to the vertical signal line 112. The power supply voltage VDD is inputted as a reset voltage of the FD node to a drain of the reset transistor 105-1, and a source of the reset transistor 105-1 is connected to the pixel connecting line 111-1. The source of the reset transistor 105-1 may also be adapted to be connected to the pixel connecting line 110-1.

Control signals TX1, RES1, ADDU1, ADDB1, SEL1 for connecting (or turning-on) or disconnecting (or turning-off) each transistor are fed to the pixel 101-1 via a control line arranged for each row. Each transistor is turned on when each control signal is at HIGH level; meanwhile, each transistor is turned off when each control signal is at LOW level.

The control signal TX1 is inputted to a gate of the transfer transistor 103-1. When the control signal TX1 becomes HIGH level, the transfer transistor 103-1 is turned on, so that an electric charge generated by the photoelectric converter 102-1 is transferred to the FD node 104-1. The FD node 104-1 has a capacitance, and the transferred electric charge is held at the capacitance.

The control signal RES1 is inputted to a gate of the reset transistor 105-1. When the control signal RES1 becomes HIGH level, the reset transistor 105-1 is turned on, so that a voltage of the pixel connecting line 111-1 is reset to the power supply voltage VDD.

The control signal SEL1 is inputted to a gate of the row select transistor 107-1. When the control signal SEL1 in the first row becomes HIGH level, the row select transistor 107-1 is turned on, so that a voltage signal according to the electric charge transferred to the FD node 104-1 is outputted to the vertical signal line 112. The vertical signal line 112 is provided with the current source 113 configured to supply an electric current in order to transmit the voltage signal to a signal processing circuit at the following stage. The signal processing circuit performs signal processing, such as A/D (Analog to Digital) conversion which involves sampling the voltage signal thereby to convert the voltage signal into a digital value, and/or CDS (Correlated Double Sampling) which involves obtaining a differential between a pixel signal and a noise thereby to reduce the noise.

The control signals ADDU1, ADDB1 are inputted to the pixel connecting transistors 108-1, 109-1, respectively. When the control signal ADDU1 becomes HIGH level, the pixel connecting transistor 108-1 is turned on, so that the FD node 104-1 and the pixel connecting line 110-1 are connected together. Likewise, when the control signal ADDB1 becomes HIGH level, the pixel connecting transistor 109-1 is turned on, so that the FD node 104-1 and the pixel connecting line 111-1 are connected together.

Thus, the pixel 101-1 of the embodiment includes the plural pixel connecting transistors and the plural pixel connecting lines. The FD nodes are connected together via the pixel connecting transistors and the pixel connecting lines thereby to average pixel signals outputted from plural photoelectric converters. As employed herein, an “average” or “averaging” of the pixel signals refers to processing in general, which adds together electric charges outputted from the plural photoelectric converters or does the like thereby to mix plural signals together to form one signal, and the “average” or “averaging” is not limited to meaning an arithmetic mean. For example, in a case where capacitance values of the FD nodes added together are different, the “average” or “averaging” may be said to be a weighted mean rather than the arithmetic mean in its strict sense; however, such a case is also construed as being included in the “average” or “averaging.” Also, in the presence of parasitic capacitances caused by the pixel connecting lines or the like, the parasitic capacitances also hold electric charges, and thus, an output signal voltage is smaller as compared to that in the absence of the parasitic capacitances and may not match the arithmetic mean; however, this is also construed as being included in the “average” or “averaging.”

In the following description, pixel rows which the pixels 101-1, 101-2, . . . , 101-n belong to are defined as a row V1, a row V2, . . . , a row Vn, respectively.

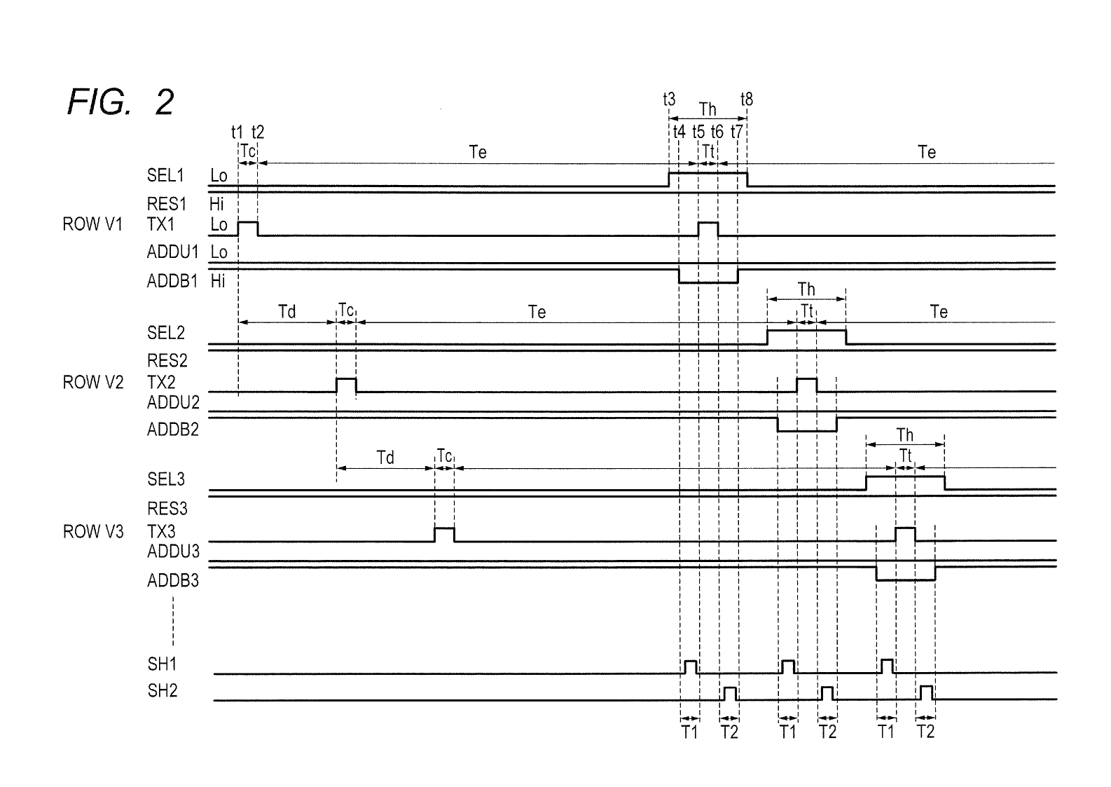

The solid-state imaging apparatus of the embodiment can operate in plural operation modes which are different in the number of pixels averaged, by changing operation timing of each transistor. The operation timings in the operation modes will be described below by using timing charts of FIGS. 2 to 4.

FIG. 2 is a timing chart illustrating how the solid-state imaging apparatus of FIGS. 1A and 1B operates to read out signals in the pixel rows in sequence. FIG. 2 illustrates an operation since the start of reset of the pixels 101-1, 101-2, 101-3 in the rows V1 to V3. The operation timings for the row V4 and the subsequent rows are omitted from an illustration because of being the same as those for the rows V1 to V3.

In the row V1, a period of time between time t1 and time t2 is a reset period Tc for the photoelectric converter 102-1; a period of time between the time t2 and time t5, an accumulation period Te; and a period of time between the time t5 and time t6, a charge transfer period Tt for the photoelectric converter 102-1. After the time t6, the accumulation period Te occurs again. In other words, in each row, after a lapse of the reset period Tc, the accumulation period Te during which an electric charge is accumulated in the photoelectric converter 102-1 and the charge transfer period Tt during which the accumulated electric charge is transferred are repeated. Also, a period of time between time t3 and time t8, during which reading of a signal for electric charge transfer or the like in the pixel takes place, is set as a row control period (or a pixel signal reading period) Th.

After a lapse of a time period Td since the time t1 of start of the reset period Tc in the row V1, the reset period Tc in the row V2 starts. After this, an operation in the row V2 is the same as that in the row V1. Likewise, also in the row V3 and the subsequent rows, the same operation is performed in sequence after each lapse of the time period Td. The operation will be described in detail below with reference to a drive timing chart for the row V1.

During a period of time before the time t1, the control signals SEL1, TX1, ADDU1 are at LOW(Lo) level, and the control signals RES1, ADDB1 are at HIGH(Hi) level. Therefore, the reset transistor 105-1 and the pixel connecting transistor 109-1 are ON, and thus, the power supply voltage VDD is applied to the FD node 104-1 and the pixel connecting line 111-1.

In the reset period Tc between the time t1 and the time t2, the control signal TX1 becomes HIGH level, and the transfer transistor 103-1 is turned on and connected to the FD node 104-1. Thereby, an electric charge accumulated in the photoelectric converter 102-1 is reset. At the time t2, the control signal TX1 returns to LOW level, and the reset of the photoelectric converter 102-1 comes to an end.

During the accumulation period Te after the time t2 of termination of the reset, the photoelectric converter 102-1 accumulates an electric charge according to incident light. At the time t5, the accumulation period Te ends, and the transfer of the electric charge accumulated in the photoelectric converter 102-1 is started. Also during the charge transfer period Tt between the time t5 and the time t6, the photoelectric converter 102-1 performs photoelectric conversion; however, the charge transfer period Tt is not included in the accumulation period because of being generally a very short time relative to the accumulation period Te.

In the row control period Th between the time t3 and the time t8, the control signal SEL1 becomes HIGH level, and the row select transistor 107-1 is turned on. At time t4, the control signal ADDB1 becomes LOW level, and the pixel connecting transistor 109-1 is turned off, so that a reset state of the FD node 104-1 is released. Thereby, the FD node 104-1 becomes electrically floating. At this time, kTC noise caused by releasing the reset state is superimposed on an output voltage from the SF transistor 106-1, provided according to the electric charge transferred to the FD node 104-1. As above, the noise is generated and read out as a pixel noise Vn to the vertical signal line 112.

A time period T1 between the time t4 and the time t5 at which the control signal TX1 makes a transition to HIGH level is a pixel noise reading period. Within the time period T1, the pixel noise Vn is sampled by the signal processing circuit at the stage following after the vertical signal line 112. A sampling signal SH1 illustrated in FIG. 2 is a control signal for sampling of the pixel noise Vn.

In the charge transfer period Tt between the time t5 and the time t6, the control signal TX1 becomes HIGH level, and the transfer transistor 103-1 becomes the ON state. Thereby, a signal electric charge generated by the photoelectric converter 102-1 performing the photoelectric conversion is transferred to the FD node 104-1. Upon completion of the transfer of the electric charge, the operation returns to the accumulation period Te again, and the photoelectric converter 102-1 starts electric charge accumulation for a next frame.

An electric charge generated by the photoelectric converter 102-1 performing photoelectric conversion during the accumulation period Te is defined as Q1. Assuming that a floating diffusion capacitance of the FD node 104-1 is C1, a voltage Q1/C1 appears in the FD node 104-1. Assuming that a signal corresponding to this voltage is Vs, a pixel signal outputted to the vertical signal line 112 via the SF transistor 106-1 and the row select transistor 107-1 is a pixel signal (Vs+Vn) having the above-mentioned pixel noise superimposed thereon.

A time period T2 between the time t6 and time t7 is a reading period for the pixel signal (Vs+Vn). The pixel signal (Vs+Vn) is sampled by the signal processing circuit, based on a sampling signal SH2, in the same manner as the above-mentioned pixel noise Vn.

At the time t7, the control signal ADDB1 becomes HIGH level again, and the FD node 104-1 returns to the reset state. At the time t8, the control signal SEL1 becomes LOW level, and the row select transistor 107-1 is controlled to be turned off.

In the signal processing circuit arranged in each column, the pixel noise Vn read out during the time period T1 and the pixel signal (Vs+Vn) read out during the time period T2 are sampled by the sampling signals SH1, SH2, respectively. The signal processing circuit obtains a signal component Vs by calculating a difference between the pixel signal (Vs+Vn) and the pixel noise Vn.

The operation timing illustrated in FIG. 2 is such that during the reading of the pixel signal, the pixel connecting transistors 108-1, 109-1 are OFF. Thus, the influences of the parasitic capacitances of the pixel connecting lines 110-1, 111-1 upon the capacitance of the FD node 104-1 are sufficiently reduced, which in turn suppresses a sensitivity reduction resulting from the pixel connecting lines.

With regard to the above-mentioned operation timing, a modification as given below is also conceivable. At the time t4, the control signal RES1 is set to LOW level to turn off the reset transistor 105-1 and thereby render the FD node 104-1 electrically floating. After that, the control signal ADDB1 is set to LOW level to turn off the pixel connecting transistor 109-1. This modification can also obtain the pixel signal in the same manner.

In the modification, parasitic capacitances are present between the gates and the sources or drains of the reset transistor 105-1 and the pixel connecting transistor 109-1. Thus, an electric potential of the FD node 104-1 decreases two times, specifically, at the time when the control signal RES1 is set to LOW level, and at the time when the control signal ADDB1 is set to LOW level. Consequently, a range of variation in the electric potential of the FD node 104-1 is limited, and hence a dynamic range may become narrow.

Meanwhile, the operation timing illustrated in FIG. 2 is such that at the time t4, the control signal ADDB1 is set to LOW level to turn off the pixel connecting transistor 109-1 and thereby render the FD node 104-1 electrically floating. According to this operation timing, the electric potential of the FD node decreases only one time. Therefore, the operation timing illustrated in FIG. 2 is more preferable in that it ensures the broader dynamic range, although the above-mentioned modification is also implementable.

Also, it is preferable that during an operation period, the control signal RES1 be maintained at HIGH level to keep the reset transistor 105-1 in the ON state and fix an electric potential of the pixel connecting lines 111-1, 110-2 in nonuse. This is for the purpose of suppressing a problem as given below: impurity diffusion regions of the sources or drains of the pixel connecting transistors 109-1, 108-2 connected to the pixel connecting lines 111-1, 110-2 are forward-biased due to junction leakage. This can also suppress electrical crosstalk between pixels via the lines which have become electrically floating.

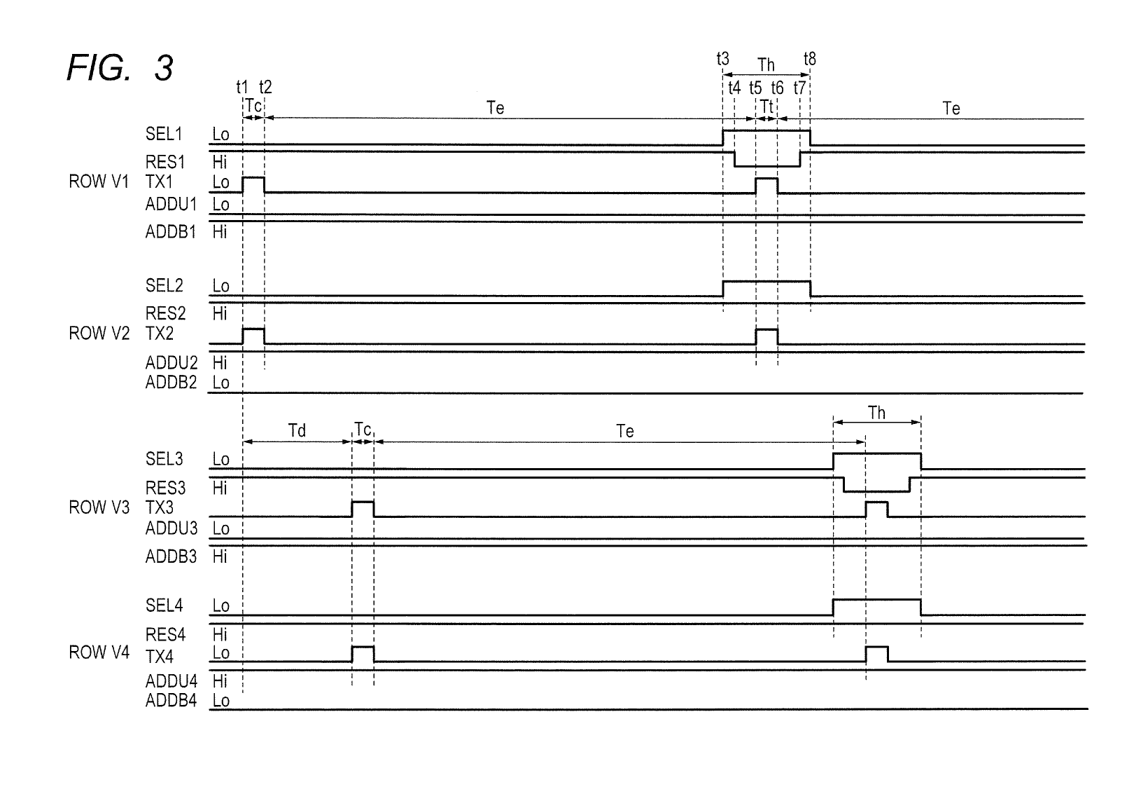

Next, FIG. 3 is a timing chart illustrating how the solid-state imaging apparatus of FIGS. 1A and 1B operates to read out an average signal of two pixels. FIG. 3 illustrates by way of example operation timing in a case where averaging of pixel signals from the pixels 101-1, 101-2 in the rows V1 and V2 and averaging of pixel signals from the pixels 101-3, 101-4 in the rows V3 and V4 are performed. Note that also for the row V5 and the subsequent rows, the same operation is performed for two rows each.

The operation of the timing chart of FIG. 3 will be described below mainly with regard to the points of difference from the timing chart illustrated in FIG. 2. In an initial state, the control signals ADDB1, ADDU2 are set to HIGH level. Also, the control signals ADDU1, ADDB2 are set to LOW level. Likewise, control signals ADDB3, ADDU4 are set to HIGH level, and control signals ADDU3, ADDB4 are set to LOW level. By the above setting, the pixel connecting transistors 109-1, 108-2, 109-3, 108-4 are turned on. Thereby, the FD node 104-1 and the FD node 104-2 are electrically connected together, and an FD node 104-3 and an FD node 104-4 are also electrically connected together. Also, pixel connecting transistors 109-2, 108-3, 109-4, 108-5 are turned off. Thereby, the FD node 104-2 and the FD node 104-3 are electrically disconnected, and the FD node 104-4 and an FD node 104-5 are also electrically disconnected.

In the reset period Tc between the time t1 and the time t2, the control signals TX1, TX2 become HIGH level, and the transfer transistors 103-1, 103-2 are turned on. Thereby, the photoelectric converters 102-1, 102-2 are reset. At the time t2, the control signals TX1, TX2 return to LOW level, and the reset of the photoelectric converters 102-1, 102-2 comes to an end. After that, a period of time between the time t2 and the time t3 is the accumulation period Te during which an electric charge is accumulated.

In the row control period Th between the time t3 and the time t8, the control signals SEL1 and SEL2 become HIGH level, and the row select transistors 107-1, 107-2 are turned on. This enables the SF transistors 106-1, 106-2 in the first and second rows to output voltage signals to the vertical signal line 112.

Then, at the time t4, the control signal RES1 becomes LOW level, and the reset transistor 105-1 is turned off. Thereby, the electrically short-circuited FD nodes 104-1 and 104-2 are released from the reset state and become electrically floating.

Then, in the charge transfer period Tt between the time t5 and the time t6, the control signals TX1, TX2 become HIGH level, and the transfer transistors 103-1, 103-2 become the ON state. Thereby, signal electric charges generated by the photoelectric converters 102-1, 102-2 performing photoelectric conversion are transferred to the FD nodes 104-1, 104-2. Upon completion of the transfer of the electric charges, the operation returns to the accumulation period Te again, and the photoelectric converters 102-1, 102-2 start electric charge accumulation for a next frame.

Electric charges generated by the photoelectric converters 102-1, 102-2 performing photoelectric conversion during the accumulation period Te are defined as Q1, Q2, respectively. A combined capacitance of the electrically connected FD nodes 104-1, 104-2 and the pixel connecting lines and the like connecting these FD nodes together is defined as C12. At this time, a voltage (Q1+Q2)/C12 obtained by averaging the signal electric charges from the photoelectric converters 102-1, 102-2 appears in the FD nodes 104-1, 104-2. In other words, according to the operation timing illustrated in FIG. 3, the signal electric charges for two pixels, namely, the pixels 101-1, 101-2, are averaged, and a resultant average is outputted.

In the period of time between the time t3 and the time t8, an averaged pixel signal is read out to the vertical signal line 112. The above-mentioned capacitance C12 includes capacitances of the FD nodes 104-1, 104-2, capacitances of the pixel connecting lines 111-1, 110-2, source-drain capacitances of the pixel connecting transistors 109-1, 108-2, channel-to-channel capacitances, and the like. Capacitances of pixel connecting lines 111-2, 110-3 can be disconnected from the FD nodes 104-1, 104-2 by turning off the pixel connecting transistor 109-2. Likewise, the capacitance of the pixel connecting line 110-1 can be disconnected by turning off the pixel connecting transistor 108-1. Thereby, the capacitances caused by the lines or the like, included in the capacitance C12, are composed only of the capacitances of the pixel connecting lines 111-1, 110-2 connecting together the FD nodes 104-1, 104-2 of the pixels 101-1, 101-2 which are averaged. Thus, the combined capacitance C12 can be reduced, so that the signal voltage (Q1+Q2)/C12 of the FD nodes can be increased. Therefore, a sensitivity reduction involved in the averaging of the pixel signals can be suppressed.

In the reading of the pixel signal to the vertical signal line 112, any one of the row select transistor 107-1 and the row select transistor 107-2 may be turned on to read out the averaged pixel signal. However, it is more preferable that both the row select transistors 107-1, 107-2 be turned on, as indicated by the period of time between the time t3 and the time t8 in the timing chart of FIG. 3. The reason for this is that both the row select transistors 107-1, 107-2 are turned on thereby to effectively increase a channel width and hence reduce the time required to output the signal to the vertical signal line 112. Further, a gate area becomes effectively large, so that noise can also be reduced.

The pixel connecting lines 111-2, 110-3 and the like are not connected to any of the FD nodes, and thus, during a period of time between the time t4 and the time t7, the same reading is possible even if control signals RES2, RES4 are at LOW level. However, it is more preferable that the control signals RES2, RES4 be set to HIGH level, as illustrated in the timing chart of FIG. 3. The control signals RES2, RES4 are set to HIGH level thereby to apply the power supply voltage VDD to the pixel connecting lines 111-2, 110-3, 111-4, 110-5 and the like which are not connected to the FD nodes, thus fixing an electric potential of these pixel connecting lines. This suppresses a problem as given below: the impurity diffusion regions of the sources or drains of the pixel connecting transistors 109-2, 108-3, 109-4, 108-5 connected to the above-mentioned pixel connecting lines are forward-biased due to junction leakage. This can also suppress electrical crosstalk between pixels via the lines which have become electrically floating.

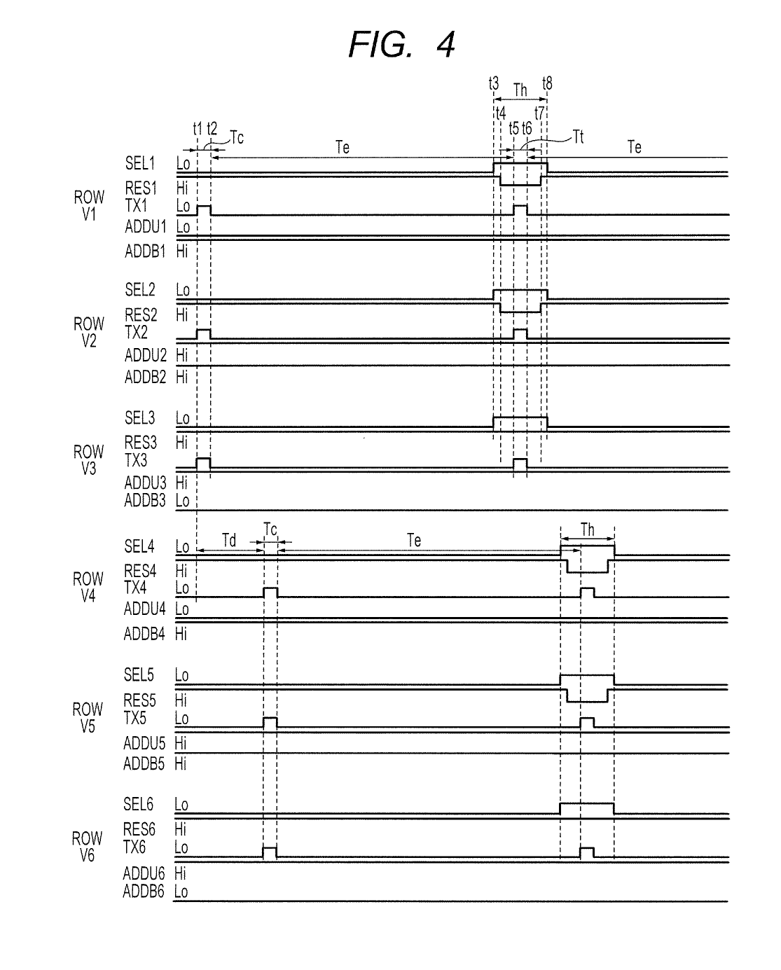

Next, FIG. 4 is a timing chart illustrating how the solid-state imaging apparatus of FIGS. 1A and 1B operates to read out an average signal of three pixels. FIG. 4 illustrates by way of example operation timing in a case where averaging of pixel signals from the pixels 101-1, 101-2, 101-3 in the rows V1, V2, V3 and averaging of pixel signals from the pixels 101-4, 101-5, 101-6 in the rows V4, V5, V6 are performed. Note that also for the row V7 and the subsequent rows, the same operation is performed for three rows each.

The operation of the timing chart of FIG. 4 will be described below mainly with regard to the points of difference from the timing charts illustrated in FIGS. 2 and 3. Since the operation in the rows V4, V5, V6 is substantially the same as the operation in the rows V1, V2, V3 except for a time difference in the time period Td, description of the operation in the rows V4, V5, V6 will be omitted.

In the initial state, the control signals ADDU1, ADDB3 are set to LOW level to set the pixel connecting transistors 108-1, 109-3 to OFF. Also, the control signals ADDB1, ADDU2, ADDB2, ADDU3 are set to HIGH level to set the pixel connecting transistors 109-1, 108-2, 109-2, 108-3 to ON. Thereby, the FD nodes 104-1, 104-2, 104-3 are electrically connected together.

In the reset period Tc between the time t1 and the time t2, the control signals TX1, TX2, TX3 become HIGH level, and the transfer transistors 103-1, 103-2, 103-3 are turned on. Thereby, the photoelectric converters 102-1, 102-2, 102-3 are reset. At the time t2, the control signals TX1, TX2, TX3 return to LOW level, and the reset of the photoelectric converters 102-1, 102-2, 102-3 comes to an end. After that, the period of time between the time t2 and the time t3 is the accumulation period Te during which an electric charge is accumulated.

Then, in the row control period Th between the time t3 and the time t8, the control signals SEL1, SEL2, SEL3 become HIGH level, and the row select transistors 107-1, 107-2, 107-3 are turned on. Thereby, the SF transistors 106-1, 106-2, 106-3 in the first, second and third rows are connected to the vertical signal line 112.

At the time t4, the control signals RES1, RES2 become LOW level, and the reset transistors 105-1, 105-2 become the OFF state. Thereby, the FD nodes 104-1, 104-2, 104-3 are released from the reset state and become electrically floating.

Then, in the charge transfer period Tt between the time t5 and the time t6, the control signals TX1, TX2, TX3 become HIGH level, and the transfer transistors 103-1, 103-2, 103-3 are turned on. Thereby, signal electric charges generated by the photoelectric converters 102-1, 102-2, 102-3 performing photoelectric conversion are transferred to the FD nodes 104-1, 104-2, 104-3. Upon completion of the transfer of the electric charges, the operation returns to the accumulation period Te again, and the photoelectric converters 102-1, 102-2, 102-3 start electric charge accumulation for a next frame.

Electric charges generated by the photoelectric converters 102-1, 102-2, 102-3 performing photoelectric conversion during the accumulation period Te are defined as Q1, Q2, Q3, respectively. A combined capacitance of the FD nodes 104-1, 104-2, 104-3 connected to one another, and the pixel connecting lines and the like connecting these FD nodes together is defined as C123. A voltage (Q1+Q2+Q3)/C123 obtained by averaging the signal electric charges appears in the FD nodes 104-1, 104-2, 104-3. In other words, according to the operation timing illustrated in FIG. 4, the signal electric charges for three pixels, namely, the pixels 101-1, 101-2, 101-3, are averaged, and a resultant average is outputted.

Capacitances of pixel connecting lines 111-3, 110-4 can be disconnected from the FD nodes 104-1, 104-2, 104-3 by turning off the pixel connecting transistor 109-3. Likewise, the capacitance of the pixel connecting line 110-1 can be disconnected by turning off the pixel connecting transistor 108-1. Thereby, the capacitances caused by the lines or the like, included in the capacitance C123, are composed only of the capacitances of the pixel connecting lines 111-1, 110-2, 111-2, 110-3 connecting the FD nodes 104-1, 104-2, 104-3 together. Thus, the combined capacitance C123 can be reduced, so that the signal voltage (Q1+Q2+Q3)/C123 of the FD nodes can be increased. Therefore, a sensitivity reduction involved in the averaging of the pixel signals can be suppressed.

In the reading of the pixel signal to the vertical signal line 112, at least one of the row select transistors 107-1, 107-2, 107-3 may be turned on to read out the averaged pixel signal, and it is not essential that all of these row select transistors be turned on. However, it is more preferable that all of the row select transistors 107-1, 107-2, 107-3 be turned on, as indicated by the period of time between the time t3 and the time t8 in the timing chart of FIG. 4. The reason for this is that all of the row select transistors 107-1, 107-2, 107-3 are turned on thereby to effectively increase the channel width and hence reduce the time required to output the signal to the vertical signal line 112. Further, the gate area becomes effectively large, so that noise can also be reduced.

The pixel connecting lines 111-3, 110-4 and the like are not connected to any of the FD nodes, and thus, during the period of time between the time t4 and the time t7, the same reading is possible even if control signals RES3, RES6 are at LOW level. However, it is more preferable that the control signals RES3, RES6 be set to HIGH level, as illustrated in the timing chart of FIG. 4. The control signals RES3, RES6 are set to HIGH level thereby to apply the power supply voltage VDD to the pixel connecting lines 111-3, 110-4, 111-6, 110-7 and the like which are not connected to the FD nodes, thus fixing an electric potential of these pixel connecting lines. This suppresses a problem as given below: the impurity diffusion regions of the sources or drains of the pixel connecting transistors 109-3, 108-4, 109-6, 108-7 connected to the above-mentioned pixel connecting lines are forward-biased due to junction leakage. This can also suppress electrical crosstalk between pixels via the lines which have become electrically floating.

Although the averaging according to the timing chart of FIG. 3 or 4 mentioned above is to average pixel signals of two or three pixels, the number of pixels averaged may be set to any number, for example, four or more. For example, in a case of averaging of k pixels, the operation for the rows V2 to V(k−1) can be performed in the same manner as that for the row V2 in FIG. 4. Also in this case, the same effects as those of the above-mentioned averaging of two or three pixels can be achieved.

More preferably, the channel widths of the pixel connecting transistors 108-1, . . . , 108-n, 109-1, . . . , 109-n are set smaller than the channel widths of the reset transistors 105-1, . . . , 105-n. Such setting of the channel widths enables a further reduction in the combined capacitance and hence an improvement in sensitivity.

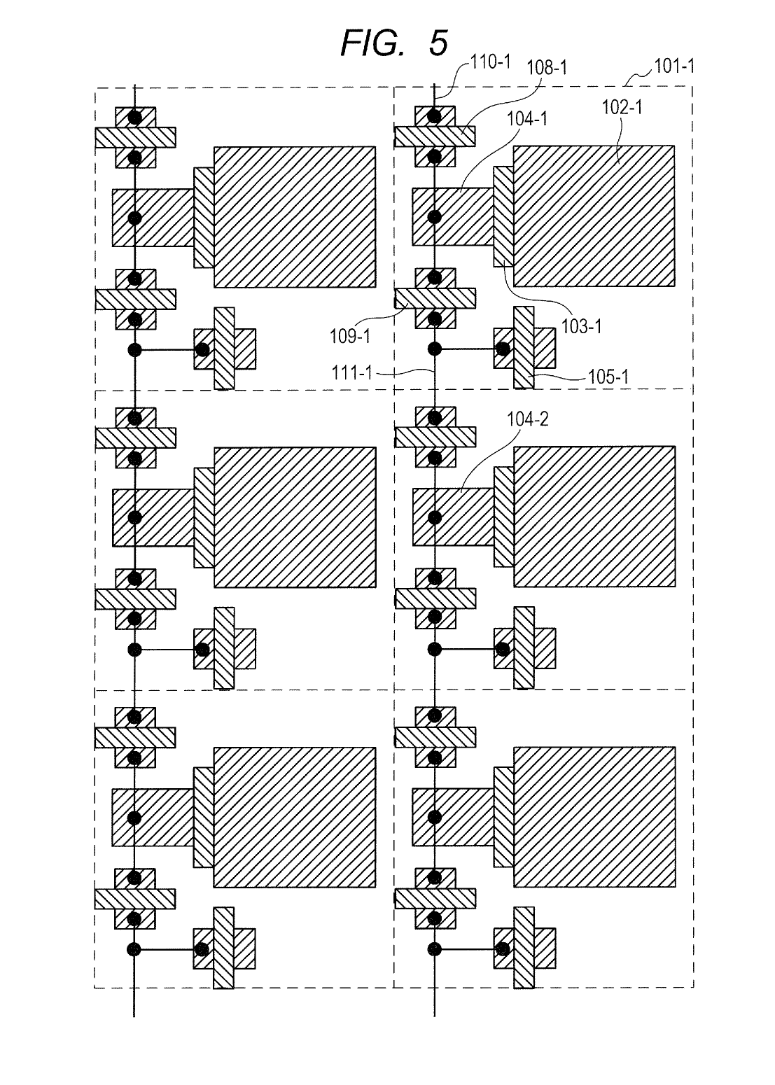

FIG. 5 is a pattern layout plan of the plural pixels included in the solid-state imaging apparatus. FIG. 5 illustrates a layout of the plural pixels 101-1, 101-2, . . . , 101-n illustrated in FIGS. 1A and 1B on the semiconductor substrate. In FIG. 5, hatched portions indicating the photoelectric converter 102-1 and the FD node 104-1 indicate impurity diffusion regions on the semiconductor substrate. Hatched portions indicating the transfer transistor 103-1, the reset transistor 105-1, and the pixel connecting transistors 108-1, 109-1 indicate gate electrodes of the transistors. Lines indicating the pixel connecting lines 110-1, 111-1 indicate lines which electrically connect the impurity diffusion regions together. The lines can be formed on a different layer from a substrate surface, with an interlayer dielectric film, such for example as silicon oxide, interposed in between, and can be configured to be electrically connected to the impurity diffusion regions in circle portions in FIG. 5. The SF transistor 106-1, the row select transistor 107-1 and the like are omitted from an illustration in FIG. 5.

Preferably, the pixel connecting transistors 108-1, 109-1 are arranged at positions as close to the FD node 104-1 as possible. More specifically, it is preferable that the pixel connecting transistor 109-1 be arranged closer to the FD node 104-1 rather than at a midpoint position between the FD nodes 104-1 and 104-2. Thereby, the capacitances of the pixel connecting transistor 108-1 and the pixel connecting line 110-1 connected to the FD node 104-1 can be reduced in any of the following cases: a case where output signals from the pixels are averaged so as to read out an averaged signal, and a case where the signals are not averaged. Therefore, the combined capacitance can be reduced, which thus enables the solid-state imaging apparatus to achieve higher sensitivity.

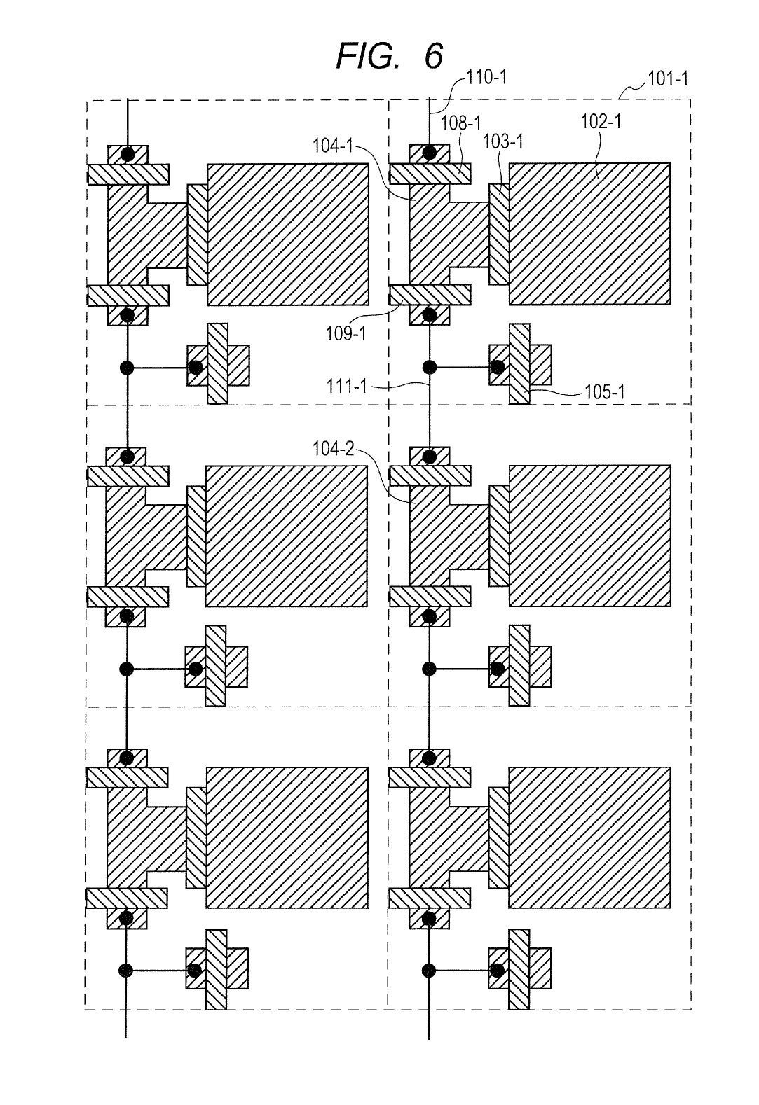

FIG. 6 is a view illustrating a modification of a pattern layout of the plural pixels. The impurity diffusion region of the FD node 104-1 and the impurity diffusion regions which form the sources or drains of the pixel connecting transistors 108-1, 109-1 share at least portions with one another. According to this configuration, connection is possible without use of the lines, and thus, the pixel connecting transistors 108-1, 109-1 can be located still closer to the FD node 104-1. Thus, the capacitance of the FD node 104-1 can be further reduced, and hence the combined capacitance can be reduced, which in turn enables the solid-state imaging apparatus to achieve still higher sensitivity. In FIG. 6, the impurity diffusion regions of both the pixel connecting transistors 108-1, 109-1 are connected to the impurity diffusion region of the FD node 104-1; however, either one of these pixel connecting transistors may be connected alone.

As described above, the solid-state imaging apparatus of the embodiment includes the pixel connecting transistor provided in each pixel and configured to set connection between the FD nodes of the pixels to the ON state or the OFF state. The number of pixels averaged can be changed by switching on or off the pixel connecting transistor. The pixel connecting line which does not contribute to the connection between the FD nodes of the pixels averaged can be set so as not to be connected to the FD nodes, which thus enables reducing the combined capacitance caused by floating diffusion, the pixel connecting line, and the like. Therefore, this enables averaging any number of pixels ranging from two pixels to all pixels, while suppressing a sensitivity reduction resulting from the connecting line for averaging. According to the embodiment, further, the pixel connecting transistor can also be turned off so as not to connect the FD nodes together in order that pixel averaging does not take place. Also in this case, setting is possible such that the pixel connecting line is not connected to the FD nodes, which thus suppresses the sensitivity reduction resulting from the connecting line. According to the embodiment, thus, the solid-state imaging apparatus having a function of averaging plural pixel signals can suppress the sensitivity reduction regardless of the presence or absence of the averaging of the pixel signals.

In the embodiment, description has been given with regard to an example in which the source of the reset transistor 105-1 is connected to the pixel connecting line 111-1. In another example, the source of the reset transistor 105-1 may be connected to the FD node 104-1 of the same pixel 101-1 as the pixel 101-1 provided with the reset transistor 105-1. Also in this case, setting is possible such that the pixel connecting line is not connected to the FD node 104-1, which thus suppresses the sensitivity reduction resulting from the connecting line. As mentioned with reference to the embodiment, however, a configuration in which the source of the reset transistor 105-1 is connected to the pixel connecting line 111-1 further has the following effect. In the solid-state imaging apparatus of the embodiment, the parasitic capacitance involved in the source of the reset transistor 105-1 is disconnected from the FD node 104-1 even when the FD nodes are not connected together so that the pixel averaging does not take place. Thereby, the solid-state imaging apparatus of the embodiment can suppress the sensitivity reduction, as compared to a configuration in which the source of the reset transistor 105-1 is connected to the FD node 104-1.

### Second Embodiment

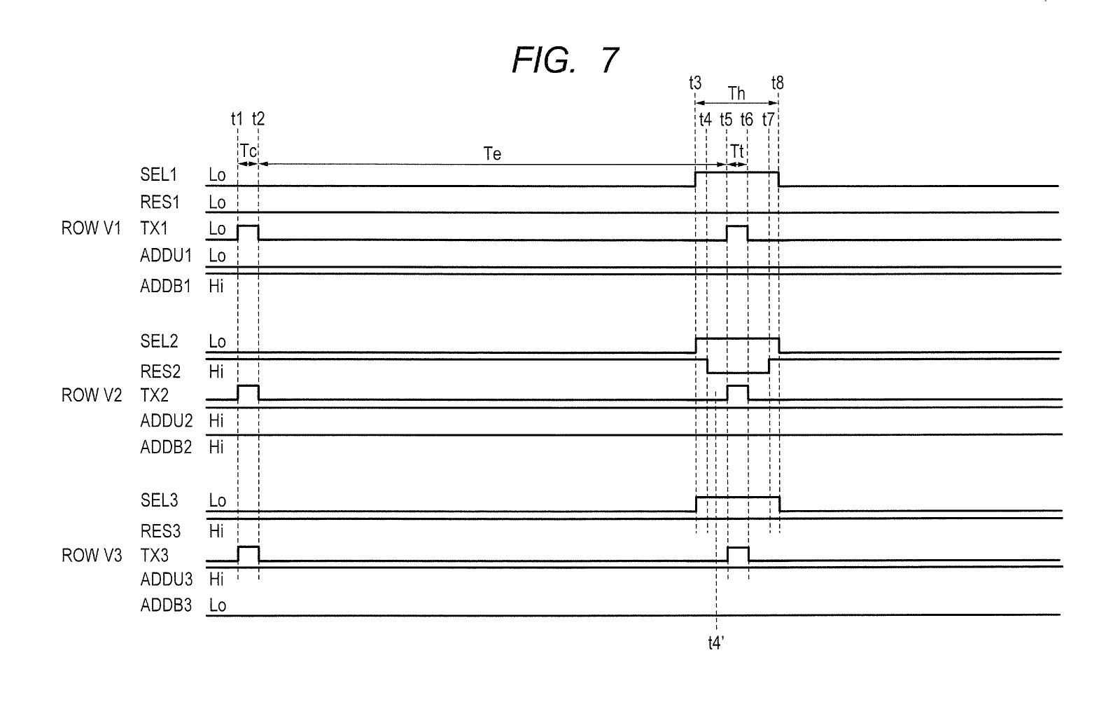

FIG. 7 is a timing chart according to a second embodiment, for reading out an average signal of three pixels. The operation for the row V4 and the subsequent rows is omitted from an illustration in FIG. 7, since the same operation is repeated in sequence after each lapse of the time period Td, as is the case with the timing chart of FIG. 4.

In the timing chart illustrated as the first embodiment in FIG. 4, the FD nodes 104-1, 104-2, 104-3 are connected together in order to average signals of three pixels. The control signals RES1, RES2 are set to HIGH level thereby to turn on the reset transistors 105-1, 105-2 and thus reset the FD nodes 104-1, 104-2, 104-3. When at the time t4, the control signals RES1, RES2 are set to LOW level to render the FD nodes floating, the voltages of the control signals RES1, RES2 on the control line simultaneously make a HIGH to LOW transition. Thus, the amount of decrease in the electric potential of the FD nodes 104-1, 104-2, 104-3 becomes large, and hence the dynamic range may become narrow.

In the timing chart of the second embodiment illustrated in FIG. 7, therefore, the control signal RES1 is always maintained at a LOW-level electric potential during the pixel signal reading period. The reset transistor 105-2 alone is used for reset, and thus, the above-described amount of decrease in the electric potential is reduced to about ½. This enables suppressing the narrowing of the dynamic range. Conversely, a configuration may also be such that the control signal RES2 is always maintained at a LOW-level electric potential thereby to use the reset transistor 105-1 alone for reset.

### Third Embodiment

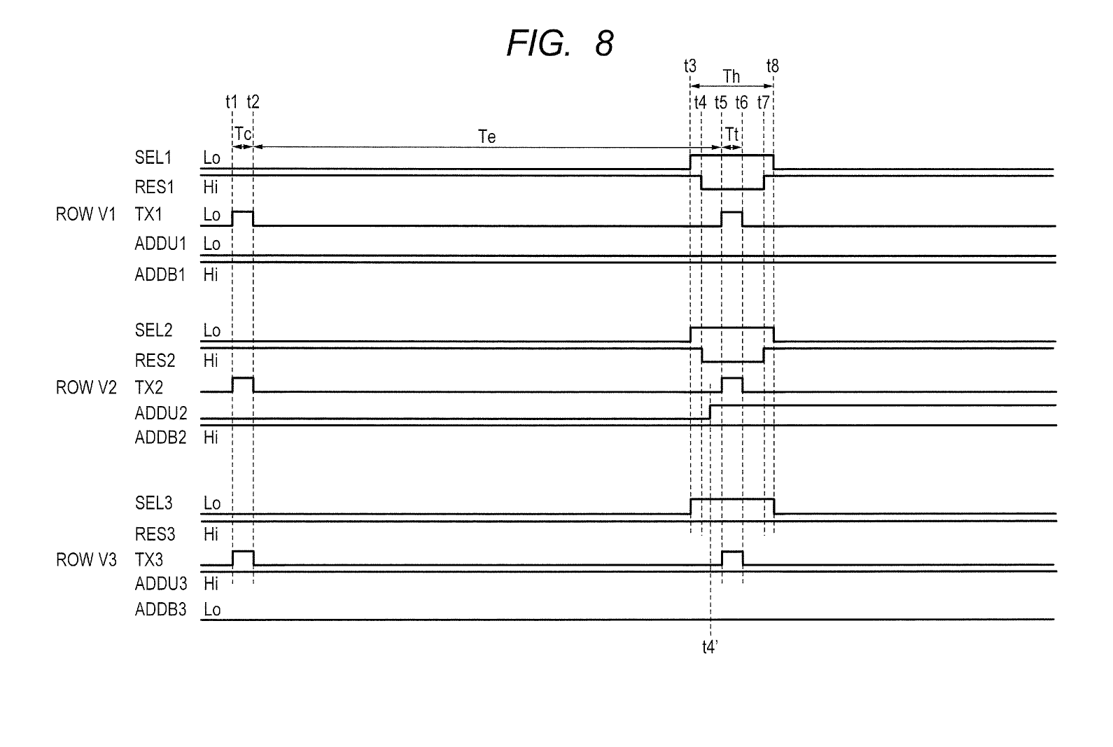

FIG. 8 is a timing chart according to a third embodiment, for reading out an average signal of three pixels. The operation for the row V4 and the subsequent rows is omitted from an illustration in FIG. 8, since the same operation is repeated in sequence after each lapse of the time period Td, as is the case with the timing chart of FIG. 4. A difference from the timing chart of FIG. 4 is that the control signal ADDU2 in the row V2, when in the initial state, is at LOW level and then this signal makes a transition to HIGH level at time t4′ between the time t4 and the time t5. In other words, during a period of time before the time t4′, the pixel connecting transistor 108-2 is OFF, and the FD node 104-1 is not connected to the FD nodes 104-2, 104-3. Thus, the reset transistor 105-1 resets the FD node 104-1, and the reset transistor 105-2 resets the FD nodes 104-2, 104-3.

As described with reference to the second embodiment, at the time t4, when the reset transistor 105-1 is turned off, the electric potential of the FD node 104-1 decreases. Likewise, at the time t4, when the reset transistor 105-2 is turned off, the electric potential of the FD nodes 104-2, 104-3 decreases. However, after that, at the time t4′, the control signal ADDU2 is set to HIGH level to turn on the pixel connecting transistor 108-2 and thereby increase the electric potential of the FD nodes 104-1, 104-2, 104-3. This reduces or eliminates a decrease in the electric potential caused by turning off the reset transistor, thus suppressing the narrowing of the dynamic range of the FD node.

### Fourth Embodiment

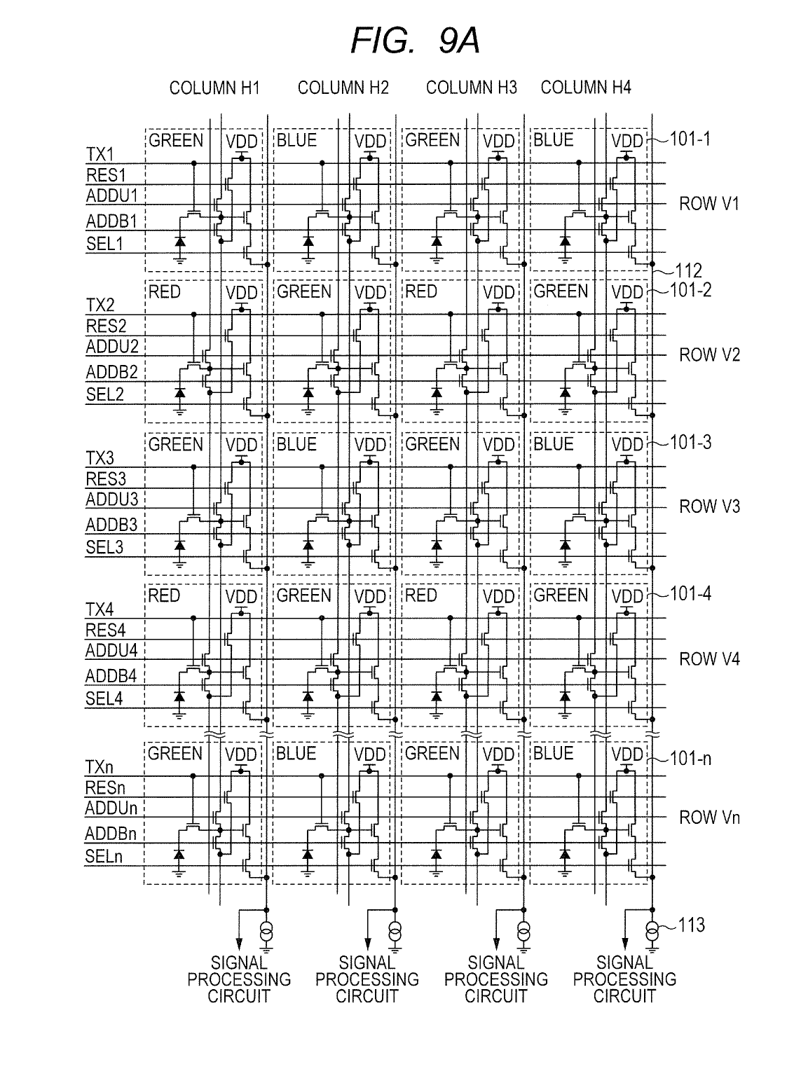

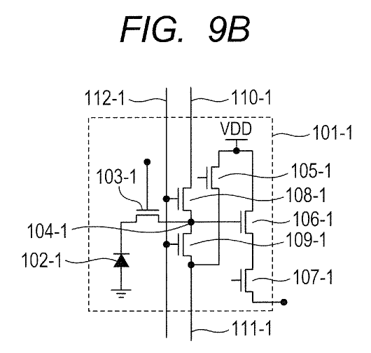

FIGS. 9A and 9B are circuit diagrams illustrating a configuration of a solid-state imaging apparatus according to a fourth embodiment of the present invention. Repetition of the same description as that with reference to FIGS. 1A and 1B will be omitted. In the solid-state imaging apparatus of the fourth embodiment, each pixel is provided with a color filter. The color filter has a function of selectively transmitting light having a specified range of wavelengths, which is incident on the photoelectric converter. A predetermined regular arrangement of the pixels including the color filters having plural different wavelength selectivities (or colors) enables obtaining image information containing color information. In the fourth embodiment, it is assumed that the pixels having the color filters of three colors, i.e. green, red and blue colors, are arranged based on Bayer arrangement.

Four columns illustrated in FIG. 9A are called a column H1, a column H2, a column H3, and a column H4, respectively, in this order as seen from the left. The pixel belonging to both the row V1 and the column H1 and the pixel belonging to both the row V2 and the column H2 are set as green; the pixel belonging to both the row V2 and the column H1, red; and the pixel belonging to both the row V1 and the column H2, blue. These four pixels are set as a unit, and other pixels are also regularly arranged in the same manner. Such an arrangement is called the Bayer arrangement.

In FIG. 9B, the pixel 101-1 further includes a pixel connecting line 112-1. The pixel connecting line 112-1 is a line via which the pixel connecting lines of the adjacent pixels in the column direction are linked together, and for example, a pixel connecting line 112-2 is connected to the pixel connecting lines 111-1, 110-3.

In the column H4, the pixel connecting transistor 109-1 is connected via the pixel connecting lines 111-1, 112-2, 110-3 to the pixel connecting transistor 108-3. In other words, the FD node 104-1 of the blue pixel 101-1 is configured to be connected to the FD node 104-3 of the likewise blue pixel 101-3. Likewise, the pixel connecting transistor 109-2 is connected via the pixel connecting lines 111-2, 112-3, 110-4 to the pixel connecting transistor 108-4. In other words, the FD node 104-2 of the green pixel 101-2 is configured to be connected to the FD node 104-4 of the likewise green pixel 101-4. Also in other pixels, according to the same rule, the FD nodes are connected together via the pixel connecting transistors and the pixel connecting lines. In other words, the pixel connecting transistors and the pixel connecting lines are arranged so that the FD nodes of the pixels of the same color among the pixels arranged in the column direction are connected together, while the FD nodes of the pixels of different colors are not connected together.

A configuration is such that the FD nodes of the pixels are connected together in the manner as above described, thereby making it possible to average pixel signals of the pixels of the same color in the Bayer arrangement. For example, first, pixel averaging is performed for odd-numbered rows (e.g. blue in a case of the column H4), namely, a row Vj, a row V(j+2), and a row V(j+4) (where j denotes an odd number). Then, pixel averaging is performed for even-numbered rows (e.g. green in a case of the column H4), namely, a row V(j+1), a row V(j+3), and a row V(j+5). By so doing, the pixel signals of three pixels arranged in the column direction can be averaged separately for each of the colors of the pixels.

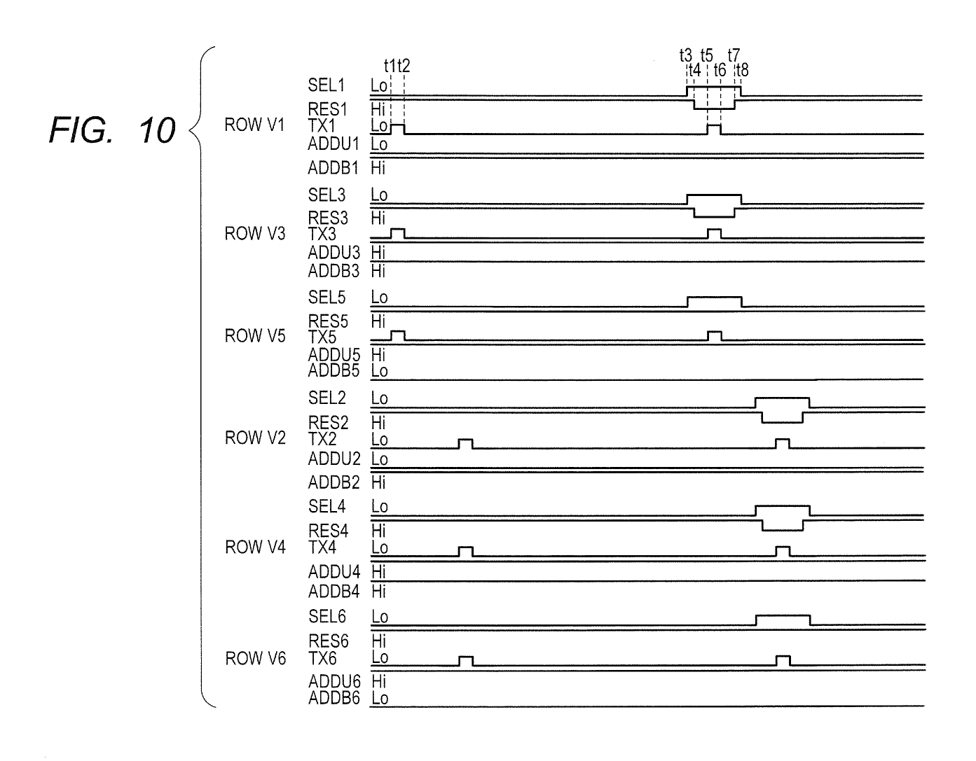

FIG. 10 is a timing chart illustrating how the solid-state imaging apparatus including the color filters in the Bayer arrangement operates to read out an average signal of three pixels. Although operation timing illustrated in the timing chart of FIG. 10 is the same as that illustrated in FIG. 4, the chart of FIG. 10 is different from that of FIG. 4 in combination of pixel rows averaged, which are driven for reading through the inputting of the control signals. In the fourth embodiment, first, the reading of pixel signals in three rows, namely, the rows V1, V3, V5, is started. Then, after a lapse of the time period Td, the reading of pixel signals in three rows, namely, the rows V2, V4, V6, is performed. Also for the row V7 and the subsequent rows, the reading is performed in the same manner. According to this reading method, as mentioned above, the pixel averaging can be performed for the odd-numbered rows and the even-numbered rows, separately from each other, and thus, the pixel signals can be averaged separately for each of the colors of the pixels.

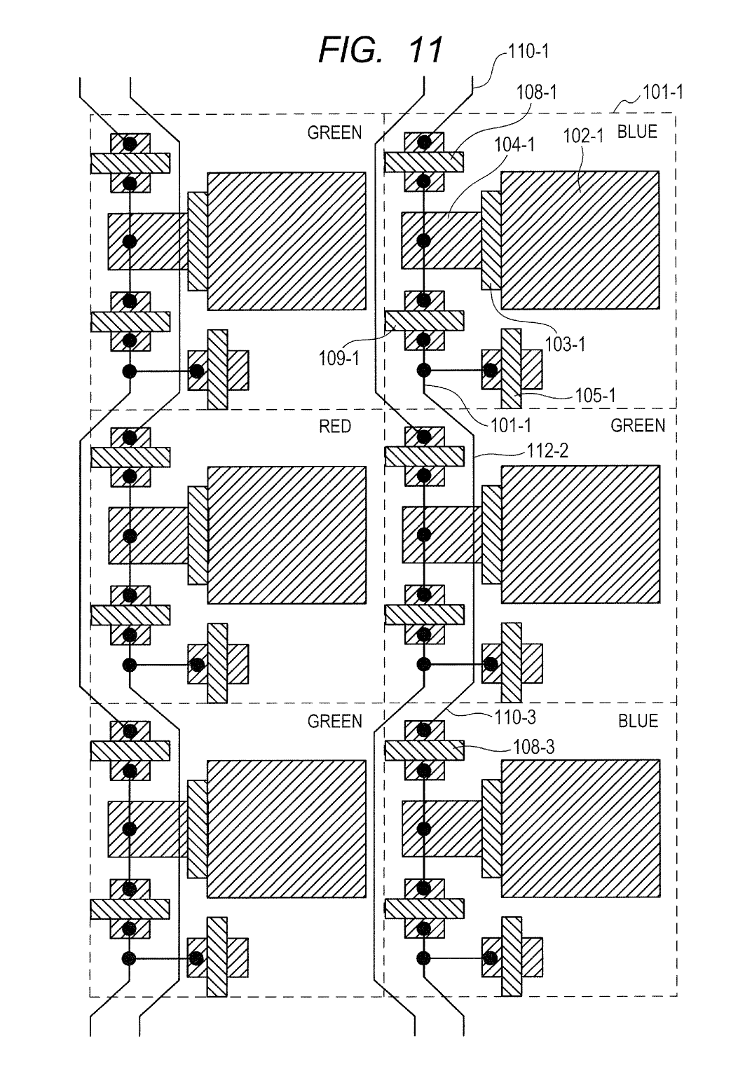

FIG. 11 is a pattern layout plan of the plural pixels included in the solid-state imaging apparatus of the fourth embodiment. For the same reason as that for the first embodiment, it is preferable that the pixel connecting transistors 108-1, 109-1 be arranged at the positions close to the FD node 104-1.

Also, in the fourth embodiment, the operation can be performed based on the timing chart which is substantially the same as that of the first embodiment, and thus, in the same manner, the fourth embodiment may also be applied to the reading operations according to the operation timings of the second and third embodiments.

According to the configuration of the fourth embodiment, as described above, the same configuration as that of any one of the first, second and third embodiments may be applied to even the solid-state imaging apparatus including the color filters of plural colors for adaptation to color imaging, and the same effects can be achieved. The FD nodes are connected together for each of the colors of the pixels and the pixel connecting lines are provided so as to enable averaging separately for each of the colors, and thereby, the same configuration as that of any one of the first, second and third embodiments may also be applied to an arrangement of pixels other than the Bayer arrangement.

### Fifth Embodiment

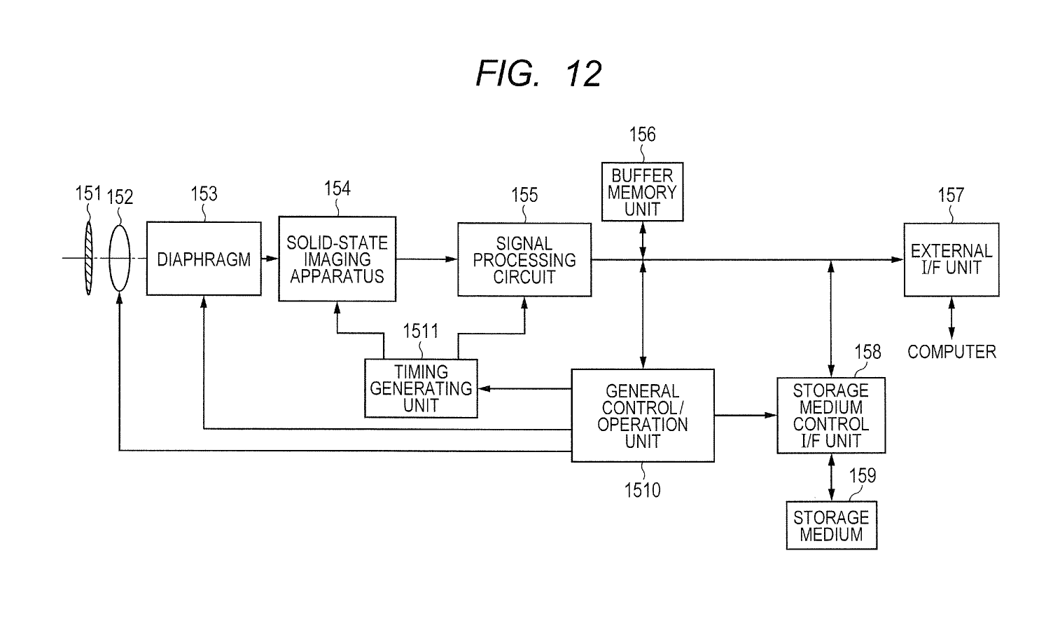

The solid-state imaging apparatuses mentioned with reference to the above-described first to fourth embodiments may be applied to various imaging systems. Examples of the imaging systems include a digital still camera, a digital camcorder, a surveillance camera, and the like. FIG. 12 illustrates a schematic diagram of the imaging system in which the solid-state imaging apparatus of any one of the first to fourth embodiments of the present invention is applied to the digital still camera as one example of the imaging system.

The imaging system illustrated by way of example in FIG. 12 includes a solid-state imaging apparatus 154, a barrier 151 for lens protection, a lens 152 configured to form an optical image of a subject on the solid-state imaging apparatus 154, and a diaphragm 153 configured to vary the amount of light passing through the lens 152. The lens 152 and the diaphragm 153 are an optical system configured to focus light on the solid-state imaging apparatus 154. The imaging system illustrated by way of example in FIG. 12 also includes a signal processing circuit 155 as a signal processing unit configured to perform processing on an output signal from the solid-state imaging apparatus 154.

The signal processing circuit 155 performs A-D conversion to convert an analog signal outputted by the solid-state imaging apparatus 154 into a digital signal. Besides, the signal processing circuit 155 also performs various corrections or compressions as needed thereby to perform an operation for outputting image data. The imaging system illustrated by way of example in FIG. 12 further includes a buffer memory unit 156 configured to temporarily store the image data, and an external interface unit (or an external I/F unit) 157 configured to communicate with an external computer or the like. The imaging system further includes a storage medium 159, such as a semiconductor memory, configured to record or read out captured image data, and a storage medium control interface unit (or a storage medium control I/F unit) 158 configured to record or read out data on or from the storage medium 159. The storage medium 159 may also be built into the imaging system, or may also be attachable and detachable to and from the imaging system.

The imaging system further includes a general control/operation unit 1510 configured to perform various operations and perform general control on the digital still camera, and a timing generating unit 1511 configured to output various timing signals to the solid-state imaging apparatus 154 and the signal processing circuit 155. Here, the timing signals or the like may be externally inputted, and the imaging system may include at least the solid-state imaging apparatus 154, and the signal processing circuit 155 configured to process the output signal from the solid-state imaging apparatus 154. As described above, the imaging system of the fifth embodiment can perform an imaging operation by applying the solid-state imaging apparatus 154 to the imaging system.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-139605, filed Jul. 7, 2014, which is hereby incorporated by reference herein in its entirety.

What is claimed is:

1. A solid-state imaging apparatus comprising:
a plurality of pixels each including:
a photoelectric converter configured to generate an electric charge by photoelectric conversion;
a transfer transistor configured to transfer the electric charge;
a floating diffusion node configured to hold the electric charge transferred by the transfer transistor;
a source follower transistor configured to output a signal based on an electric potential of the floating diffusion node;
a first pixel connecting transistor and a second pixel connecting transistor each having a drain node and a source node, one of the drain node and the source node being connected to the floating diffusion node;
a first pixel connecting line connected to the other of the drain node and the source node of the first pixel connecting transistor; and
a second pixel connecting line connected to the other of the drain node and the source node of the second pixel connecting transistor,
wherein the first pixel connecting line included in a first pixel of the plurality of pixels is connected to the second pixel connecting line included in a second pixel of the plurality of pixels, and
wherein the second pixel connecting line included in the first pixel is connected to the first pixel connecting line included in a third pixel of the plurality of pixels.

2. The solid-state imaging apparatus according to claim 1, comprising an operation mode in which the first pixel connecting transistor and the second pixel connecting transistor of the first pixel are both turned on, before the electric charge is transferred from the photoelectric converter of the first pixel to the floating diffusion node thereof.

3. The solid-state imaging apparatus according to claim 1, comprising an operation mode in which the first pixel connecting transistor and the second pixel connecting transistor of the first pixel are both turned off, before the electric charge is transferred from the photoelectric converter of the first pixel to the floating diffusion node thereof.

4. The solid-state imaging apparatus according to claim 1,
wherein the plurality of pixels are arranged in matrix,
wherein the first pixel and the second pixel are adjacent to each other in a column direction, and
wherein the first pixel and the third pixel are adjacent to each other in the column direction.

5. The solid-state imaging apparatus according to claim 1, wherein the first pixel connecting transistor of the first pixel is arranged closer to the floating diffusion node of the first pixel relative to a midpoint position between the floating diffusion node of the first pixel and the floating diffusion node of the second pixel.

6. The solid-state imaging apparatus according to claim 5, wherein an impurity diffusion region which forms the source or drain of the first pixel connecting transistor or the second pixel connecting transistor of the first pixel shares at least a portion common with an impurity diffusion region of the floating diffusion node of the first pixel.

7. The solid-state imaging apparatus according to claim 1,
wherein each of the pixels further includes a color filter configured to selectively transmit light having a specified range of wavelengths, which is incident on the photoelectric converter,
wherein the plurality of pixels include a predetermined arrangement of the pixels including the color filters having a plurality of different wavelength selectivities, and
wherein the first pixel, the second pixel and the third pixel include the color filters having the same wavelength selectivities.

8. The solid-state imaging apparatus according to claim 1,
wherein each of the plurality of pixels further includes a reset transistor having a drain node and a source node, and
wherein a reset voltage is inputted to one of the drain node and the source node of the reset transistor of each of the pixels, and the other of the drain node and the source node of the reset transistor is connected to the first pixel connecting line or the second pixel connecting line included in each of the pixels.

9. The solid-state imaging apparatus according to claim 8, comprising an operation mode in which at least one of the reset transistors, which is the reset transistor of the first pixel, the second pixel or the third pixel and is electrically connected to the floating diffusion node of the first pixel, is always OFF during a pixel signal reading period.

10. The solid-state imaging apparatus according to claim 8, comprising an operation mode in which any one of the first pixel connecting transistor and the second pixel connecting transistor of the first pixel changes from OFF to ON, in the pixel signal reading period, and in a period of time before the electric charge is transferred from the photoelectric converter of the first pixel to the floating diffusion node thereof.

11. The solid-state imaging apparatus according to claim 1, wherein a channel width of the first pixel connecting transistor or the second pixel connecting transistor of each of the pixels is smaller than a channel width of the reset transistor of each of the pixels.

12. An imaging system comprising:
a solid-state imaging apparatus comprising:
a plurality of pixels each including:
a photoelectric converter configured to generate an electric charge by photoelectric conversion;
a transfer transistor configured to transfer the electric charge;
a floating diffusion node configured to hold the electric charge transferred by the transfer transistor;
a source follower transistor configured to output a signal based on an electric potential of the floating diffusion node;
a first pixel connecting transistor and a second pixel connecting transistor each having a drain node and a source node, one of the drain node and the source node being connected to the floating diffusion node;
a first pixel connecting line connected to the other of the drain node and the source node of the first pixel connecting transistor; and
a second pixel connecting line connected to the other of the drain node and the source node of the second pixel connecting transistor,
wherein the first pixel connecting line included in a first pixel of the plurality of pixels is connected to the second pixel connecting line included in a second pixel of the plurality of pixels, and
wherein the second pixel connecting line included in the first pixel is connected to the first pixel connecting line included in a third pixel of the plurality of pixels; and
a signal processing unit configured to generate an image by using a signal outputted by the solid-state imaging apparatus.
